(19) United States
(12) Patent Application Publication
(10) Pub. No.: US 2023/0147514 A1
(43) Pub. Date: May 11, 2023

(54) LIGHT-EMITTING ELEMENT, AND DISPLAY DEVICE

(71) Applicant: SHARP KABUSHIKI KAISHA, Sakain City, Osaka (JP)

(72) Inventors: Keisuke KITANO, Sakai City, Osaka (JP); Masaki YAMAMOTO, Sakai City, Osaka (JP)

(21) Appl. No.: 17/909,630

(22) PCT Filed: Mar. 26, 2020
(86) PCT No.: PCT/JP2020/013726

§ 371 Date: Sep. 6, 2022

(51) Int. Cl. H10K 50/852; H10K 50/115; H10K 59/35

(52) U.S. Cl. CPC H10K 50/852; H10K 50/115; H10K 59/35; H10K 59/12

(57) ABSTRACT

A light-emitting element includes a light-emitting layer including quantum dots, a selectively reflective layer, the selectively reflective layer having a reflection band having a higher reflectivity than a reflectivity of another band, and a wavelength at a long wavelength end in the reflection band of the selectively reflective layer is longer than a wavelength having a half value of a peak value of a light emission spectrum due to electroluminescence of the quantum dots at a shorter wavelength side than a peak wavelength of the light emission spectrum due to the electroluminescence of the quantum dots, and is shorter than a wavelength having the half value of the peak value of the light emission spectrum due to the electroluminescence of the quantum dots at a longer wavelength side than the peak wavelength of the light emission spectrum due to the electroluminescence of the quantum dots.

### TECHNICAL FIELD

The present invention relates to a light-emitting element and a display device.

### BACKGROUND ART

In recent years, a variety of flat panel displays have been developed, and in particular, a display device that includes a Quantum dot Light Emitting Diode (QLED) or an Organic dot Light Emitting Diode (OLED) as an electroluminescent element has attracted attention.

PTL 1 relates to a vertical resonance type surface emitting laser in which a light-emitting layer including quantum dots is used.

### CITATION LIST

### Patent Literature

PTL 1: JP 2006-229194 A (published on Aug. 31, 2006)

### SUMMARY OF INVENTION

### Technical Problem

The light emission line width of one quantum dot is very narrow. On the other hand, the light emission line width of a plurality of quantum dots is wider than the light emission line width of one quantum dot due to dispersion of granularities, composition ratios, and the like. A light-emitting element including a quantum dot typically includes a plurality of quantum dots.

Thus, conventional light-emitting elements including quantum dots have a problem in that the light emission line width thereof is wide.

In PTL 1, the principles of a laser, that is, induced emission and resonance, are used in order to solve this problem.

The present invention has been made in view of the above problem, and an object of the present invention is to narrow a light emission line width of a light-emitting element including quantum dots by using another method.

### Solution to Problem

In order to solve the problem described above, a light-emitting element according to an aspect of the present invention includes a reflective electrode, a transparent electrode, a light-emitting layer provided between the reflective electrode and the transparent electrode, the light-emitting layer including quantum dots, and a selectively reflective layer provided at an opposite side to the light-emitting layer with respect to the transparent electrode, the selectively reflective layer having a reflection band having a higher reflectivity than a reflectivity of another band, and a wavelength at a long wavelength end in the reflection band of the selectively reflective layer is longer than a wavelength at which a light emission spectrum due to electroluminescence of the quantum dots has a half value of a peak value of the light emission spectrum due to the electroluminescence of the quantum dots at a shorter wavelength side than a peak wavelength of the light emission spectrum due to the electroluminescence of the quantum dots, and is shorter than a wavelength at which the light emission spectrum due to the electroluminescence of the quantum dots has the half value of the peak value of the light emission spectrum due to the electroluminescence of the quantum dots at a longer wavelength side than the peak wavelength of the light emission spectrum due to the electroluminescence of the quantum dots.

In order to solve the problem described above, a light-emitting element according to an aspect of the present invention includes a first transparent electrode, a second transparent electrode, a light-emitting layer provided between the first transparent electrode and the second transparent electrode, the light-emitting layer including quantum dots, a first selectively reflective layer provided at an opposite side to the light-emitting layer with respect to the first transparent electrode, the first selectively reflective layer having a reflection band having a higher reflectivity than a reflectivity of another band, and a second selectively reflective layer provided at an opposite side to the light-emitting layer with respect to the second transparent electrode, the second selectively reflective layer having a reflection band having a higher reflectivity than a reflectivity of another band, a wavelength at a long wavelength end in the reflection band of the first selectively reflective layer is longer than a wavelength at which a light emission spectrum due to electroluminescence of the quantum dots has a half value of a peak value of the light emission spectrum due to the electroluminescence of the quantum dots at a shorter wavelength side than a peak wavelength of the light emission spectrum due to the electroluminescence of the quantum dots, and is shorter than a wavelength at which the light emission spectrum due to the electroluminescence of the quantum dots has the half value of the peak value of the light emission spectrum due to the electroluminescence of the quantum dots at a longer wavelength side than the peak wavelength of the light emission spectrum due to the electroluminescence of the quantum dots, and a wavelength at a long wavelength end in the reflection band of the second selectively reflective layer is longer than the wavelength at which the light emission spectrum due to the electroluminescence of the quantum dots has the half value of the peak value of the light emission spectrum due to the electroluminescence of the quantum dots at the shorter wavelength side than the peak wavelength of the light emission spectrum due to the electroluminescence of the quantum dots, and is shorter than the wavelength at which the light emission spectrum due to the electroluminescence of the quantum dots has the half value of the peak value of the light emission spectrum due to the electroluminescence of the quantum dots at the longer wavelength side than the peak wavelength of the light emission spectrum due to the electroluminescence of the quantum dots.

### Advantageous Effects of Invention

With the light-emitting element according to the aspect of the present invention, a light emission line width of the light-emitting layer including the quantum dots can be narrowed.

### BRIEF DESCRIPTION OF DRAWINGS

FIG. 1 is a flowchart illustrating an example of a manufacturing method for a display device.

FIG. 2 is a cross-sectional view illustrating an example of a configuration of a display region of a display device.

FIG. 3 is a cross-sectional view illustrating a schematic configuration of a light-emitting element layer in a display device according to a first embodiment of the present invention.

FIG. 4 is a schematic cross-sectional view illustrating reflection and transmission in the light-emitting element layer in a blue pixel illustrated in FIG. 3.

FIG. 5 is a diagram illustrating, on the upper side, a graph showing a light emission spectrum due to electroluminescence of a light-emitting element layer according to a comparative example, and illustrating, on the lower side, a graph showing a light emission spectrum due to electroluminescence from the example of the light-emitting element layer illustrated in FIG. 4.

FIG. 6 is a diagram illustrating, on the upper side, a graph showing a light emission spectrum due to electroluminescence of the light-emitting element layer according to the comparative example, and illustrating, on the lower side, a graph showing a light emission spectrum due to electroluminescence from another example of the light-emitting element layer 5 illustrated in FIG. 4.

FIG. 7 is a cross-sectional view illustrating a schematic configuration of an example in which a selectively reflective layer illustrated in FIG. 3 is a dielectric multilayer film.

FIG. 8 is a cross-sectional view illustrating a schematic configuration of a light-emitting element layer according to a modified example of the first embodiment of the present invention.

FIG. 9 is a cross-sectional view illustrating a schematic configuration of a light-emitting element layer according to another modified example of the first embodiment of the present invention.

FIG. 10 is a cross-sectional view illustrating a schematic configuration of a light-emitting element layer in a display device according to a second embodiment of the present invention.

FIG. 11 is a cross-sectional view illustrating a schematic configuration of a light-emitting element layer according to a modified example of the second embodiment of the present invention.

FIG. 12 is a cross-sectional view illustrating another example of a configuration of a display region of the display device.

FIG. 13 is a cross-sectional view illustrating a schematic configuration of a light-emitting element layer in a display device according to a third embodiment of the present invention.

FIG. 14 is a schematic cross-sectional view illustrating reflection and transmission in the light-emitting element layer in a blue pixel illustrated in FIG. 13.

FIG. 15 is a cross-sectional view illustrating a schematic configuration of a light-emitting element layer in a display device according to a fourth embodiment of the present invention.

### DESCRIPTION OF EMBODIMENTS

### First Embodiment

Hereinafter, an embodiment of the present invention will be described in detail with reference to the drawings. However, shapes, dimensions, relative arrangements, and the like illustrated in the drawings are merely exemplary, and the scope of the present invention should not be construed as limiting due to these.

A display device 2 according to a first embodiment of the present invention is a one-sided light-emitting type.

### Manufacturing Method of Display Device and Configuration Thereof

In the following description, the “same layer” means that it is formed through the same process (film formation step), the “lower layer” means that it is formed through a process before that of the compared layer, and the “upper layer” means that it is formed through a process after that of the compared layer.

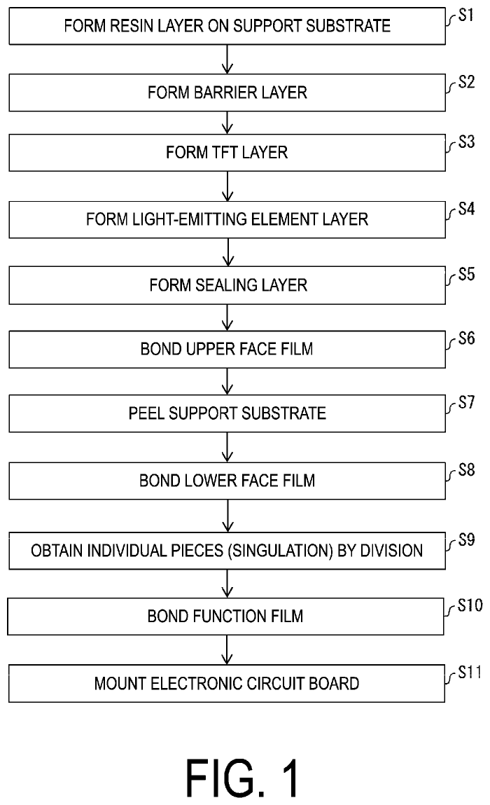

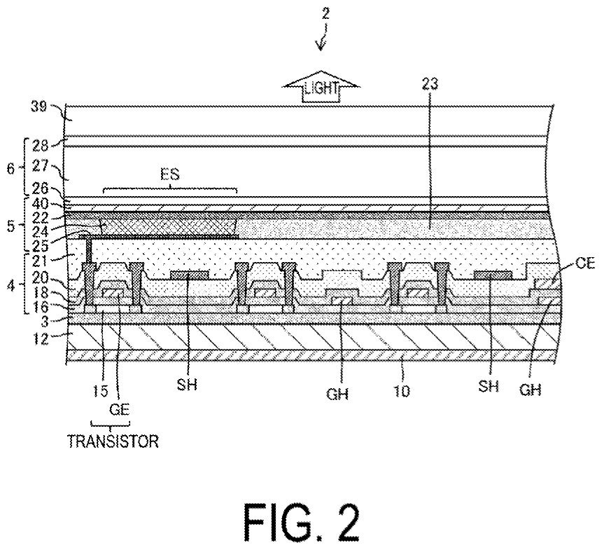

FIG. 1 is a flowchart illustrating an example of a manufacturing method of a display device. FIG. 2 is a schematic cross-sectional view illustrating an example of a configuration of a display region of the display device 2.

In a case where a flexible display device is manufactured, as illustrated in FIG. 1 and FIG. 2, first, a resin layer 12 is formed on a support substrate (a mother glass, for example) having transparency (step S1). Next, a barrier layer 3 is formed (step S2). Next, a thin film transistor layer (TFT layer) 4 is formed (step S3). Next, a light-emitting element layer 5 of a top-emitting type is formed (step S4). Next, a sealing layer 6 is formed (step S5). Next, an upper face film is bonded on the sealing layer 6 (step S6).

Next, the support substrate is peeled from the resin layer 12 due to irradiation with a laser light or the like (step S7). Next, a lower face film 10 is bonded to the lower face of the resin layer 12 (step S8). Next, a layered body including the lower face film 10, the resin layer 12, the barrier layer 3, the thin film transistor layer 4, the light-emitting element layer 5, and the sealing layer 6 is divided to obtain a plurality of individual pieces (step S9). Next, a function film 39 is bonded to the obtained individual piece (step S10). Next, an electronic circuit board (for example, an IC chip or a Flexible Printed Circuit (FPC)) is mounted at a part (terminal portion) of a region (a non-display region or a frame region) positioned further outward than a display region where a plurality of subpixels are formed (step S11). Note that steps S1 to S11 are executed by a display device manufacturing apparatus (including a film formation apparatus that executes the process from steps S1 to S5).

Examples of the material of the resin layer 12 include polyimide and the like. A portion of the resin layer 12 can be replaced with two layers of resin films (for example, polyimide films) and an inorganic insulating film sandwiched therebetween.

The barrier layer 3 is a layer that inhibits foreign matter such as water and oxygen from entering the thin film transistor layer 4 and the light-emitting element layer 5. For example, the barrier layer can be constituted of a silicon oxide film, a silicon nitride film, or a silicon oxynitride film, or a layered film thereof formed by Chemical Vapor Deposition (CVD).

The thin film transistor layer 4 includes a semiconductor film 15, an inorganic insulating film 16 (gate insulating film) that is an upper layer than the semiconductor film 15, a gate electrode GE and a gate wiring line GH1 that are upper layers than the inorganic insulating film 16, an inorganic insulating film 18 (interlayer insulating film) that is an upper layer than the gate electrode GE and the gate wiring line GH, a capacitance electrode CE that is an upper layer than the inorganic insulating film 18, an inorganic insulating film 20 (interlayer insulating film) that is an upper layer than the capacitance electrode CE, a source wiring line SH that is an upper layer than the inorganic insulating film 20, and a flattening film 21 (interlayer insulating film) that is an upper layer than the source wiring line SH.

The semiconductor film 15 is formed of low-temperature polysilicon (LTPS) or an oxide semiconductor (for example, an In—Ga—Zn—O based semiconductor), for example. FIG. 2 illustrates the transistor that has a top gate structure, but the transistor may have a bottom gate structure.

The gate electrode GE, the gate wiring line GH and the capacitance electrode CE, and the source wiring line SH are each constituted by, for example, a single layer film containing at least one of aluminum, tungsten, molybdenum, tantalum, chromium, titanium, and copper, or a layered film thereof.

The inorganic insulating films 16, 18, and 20 can be constituted by, for example, a silicon oxide (SiOx) film, a silicon nitride (SiNx) film, or a silicon oxynitride (SiNO) film formed by CVD, or a layered film thereof. The flattening film 21 can be constituted by a coatable organic material such as polyimide or acrylic.

The light-emitting element layer 5 includes a cathode 25 (cathode electrode, or so-called pixel electrode) provided as an upper layer than the flattening film 21, an edge cover 23 having an insulating property and covering an edge of the cathode 25, an active layer 24 that is an ElectroLuminescence (EL) layer provided as an upper layer than the edge cover 23, and an anode 22 (anode electrode, or so-called common electrode) provided as an upper layer than the active layer 24, and further includes a selectively reflective layer 40 provided as an upper layer than the anode 22. The edge cover 23 is formed by applying an organic material such as polyimide or acrylic and then patterning the organic material by photolithography, for example.

For each subpixel, a light-emitting element ES (electroluminescent element) including the cathode 25 having an island shape, the active layer 24, and the anode 22 and being a QLED is formed in the light-emitting element layer 5, and a subpixel circuit for controlling the light-emitting element ES is formed in the thin film transistor layer 4.

For example, the active layer 24 is constituted by layering an electron injection layer, an electron transport layer, a light-emitting layer including quantum dots, a hole transport layer, and a hole injection layer in this order, from the lower layer side. The light-emitting layer is formed, together with the hole transport layer, into an island shape at an opening of the edge cover 23 (for each subpixel) by photolithography. Other layers are formed in an island shape or a solid-like shape (common layer). In addition, it is also possible to adopt a configuration in which one or more layers among the electron injection layer, the electron transport layer, the hole transport layer, and the hole injection layer are not formed.

A material to be used for the hole injection layer is not particularly limited as long as the material is a hole injection material capable of stabilizing the injection of positive holes into the light-emitting layer. Examples of the hole injection material include conductive polymers such as arylamine derivatives, porphyrin derivatives, phthalocyanine derivatives, carbazole derivatives, polyaniline derivatives, polythiophene derivatives, and polyphenylene vinylene derivatives. Note that the material to be used for the hole injection layer is more preferably poly (3,4-ethylenedioxythiophene)-polystyrene sulfonic acid (PEDOT-PSS). The PEDOT-PSS improves the efficiency of light emission resulting from recombination of electrons and positive holes in a quantum dot light-emitting layer, and thus exhibits the effect of improving the light-emission characteristics of an electroluminescent element.

A constituent material of the hole transport layer is not particularly limited as long as the material is a hole transport material capable of stabilizing the transport of the positive holes into the quantum dot light-emitting layer 3. The hole transport material preferably has high hole mobility. Furthermore, the hole transport material is preferably a material (electron blocking material) capable of preventing the penetration of electrons that have traveled from the cathode electrode. This makes it possible to increase a recombination efficiency of the holes and the electrons within the light-emitting layer.

Examples of materials to be used for the hole transport layer include arylamine derivatives, anthracene derivatives, carbazole derivatives, thiophene derivatives, fluorene derivatives, distyrylbenzene derivatives, and spiro compounds. Note that materials to be used for the hole transport layers 2R and 2G are more preferably polyvinyl carbazole (PVK) or poly[(9,9-dioctylfluorenyl-2,7-diyl)-co-(4,4′-(N-(4-sec-butylphenyl)) diphenylamine)] (TFB). The PVK and the TFB improve the efficiency of light emission resulting from recombination of the electrons and the positive holes in the quantum dot light-emitting layer, and thus exhibit the effect of improving the light-emission characteristics of the electroluminescent element.

Examples of the method of forming the hole transport layer and the hole injection layer include vapor deposition, a printing method, an ink-jet method, a spin coating method, a casting method, a dipping method, a bar coating method, a blade coating method, a roll coating method, a gravure coating method, a flexographic printing method, a spray coating method, a photolithography method, and a self-organization method (layer-by-layer method, self-assembled monolayer method), but the method is not limited thereto. Among these, the vapor deposition, the spin coating method, the ink-jet method, or the photolithography method is preferably used.

The quantum dots may include one or a plurality of semiconductor materials selected from a group including Cd, S, Te, Se, Zn, In, N, P, As, Sb, Al, Ga, Pb, Si, Ge, Mg, and compounds thereof. The quantum dots may be a two-component core type, a three-component core type, a four-component core type, a core-shell type, or a core multi-shell type. Further, the quantum dots may include doped nanoparticles, or may include a compositionally graded structure.

A method of forming the light-emitting layer is not particularly limited as long as the method is capable of forming a fine pattern required for the electroluminescent element. Examples include vapor deposition, a printing method, an ink-jet method, a spin coating method, a casting method, a dipping method, a bar coating method, a blade coating method, a roll coating method, a gravure coating method, a flexographic printing method, a spray coating method, a photolithography method, and a self-organization method (layer-by-layer method, self-assembled monolayer method). Among these, the vapor deposition, the spin coating method, the ink-jet method, or the photolithography method is preferably used. Additionally, a thickness of the light-emitting layer is not particularly limited as long as the thickness is capable of expressing a function of providing a place for recombination between the electrons and the positive holes to achieve light emission, and can be, for example, from about 1 nm to 200 nm.

Examples of the vapor deposition include a vacuum vapor deposition technique, a sputtering method, and an ion plating method, and specific examples of the vacuum vapor deposition technique include resistance heating vapor deposition, flash vapor deposition, arc vapor deposition, laser vapor deposition, high frequency heating vapor deposition, and electron beam vapor deposition.

When the light-emitting layer is formed by application of a coating liquid such as a spin coating method or an ink-jet method, a solvent of the coating liquid is not particularly limited as long as the solvent can dissolve or disperse the constituent material of the light-emitting layer, and examples thereof include toluene, xylene, cyclohexanone, cyclohexanol, tetralin, mesitylene, methylene chloride, tetrahydrofuran, dichloroethane, and chloroform.

The active layer 24 may further include an intermediate layer between the light-emitting layer and the electron transport layer.

The cathode 25 is a reflective electrode that is constituted by layering, for example, Indium Tin Oxide (ITO) and silver (Ag) or an alloy containing Ag, or constituted by a material containing Ag or Al and that has light reflectivity. The anode 22 is a transparent electrode constituted by a thin film of Ag, Au, Pt, Ni, or Ir, a thin film of an MgAg alloy, or a conductive material having transparency such as ITO, or Indium Zinc Oxide (IZO). When the display device is not a top-emitting type display device but is a bottom-emitting type display device, the lower face film 10 and the resin layer 12 have transparency, the cathode 25 is a transparent electrode, and the anode 22 is a reflective electrode.

The selectively reflective layer 40 has a reflection band having a higher reflectivity than those of other bands. Details will be described below.

In the light-emitting element ES, the positive holes and the electrons recombine inside the light-emitting layer in response to a drive current between the anode 22 and the cathode 25, and when excitons generated due to this recombination transition from the Lowest Unoccupied Molecular Orbital (LUMO) or the conduction band to the Highest Occupied Molecular Orbital (HOMO) or the valence band of the quantum dots, light is emitted.

The sealing layer 6 has transparency, and includes an inorganic sealing film 26 for covering the anode 22, an organic buffer film 27 provided as an upper layer than the inorganic sealing film 26, and an inorganic sealing film 28 provided as an upper layer than the organic buffer film 27. The sealing layer 6 covering the light-emitting element layer 5 inhibits foreign matters such as water and oxygen from penetrating the light-emitting element layer 5.

Each of the inorganic sealing film 26 and the inorganic sealing film 28 is an inorganic insulating film and can be formed of, for example, a silicon oxide film, a silicon nitride film, or a silicon oxynitride film, or a layered film of these, formed by CVD. The organic buffer film 27 is a transparent organic film having a flattening effect and can be formed of a coatable organic material such as an acrylic. The organic buffer film 27 can be formed, for example, by ink-jet application, and a bank for stopping droplets may be provided in a non-display region.

The lower face film 10 is, for example, a PET film bonded to a lower face of the resin layer 12 after the support substrate is peeled, to achieve a display device having excellent flexibility. The function film 39 has at least one of an optical compensation function, a touch sensor function, and a protection function, for example.

The display device being flexible has been described above, but when the display device is manufactured as a display device being non-flexible, because formation of the resin layer, replacement of the base material and the like are typically not required, processing proceeds to step S9 after the layering process on the glass substrate of steps S2 to S5 is executed, for example. Furthermore, when a display device being non-flexible is manufactured, a sealing member having transparency may be caused to adhere using a sealing adhesive instead of or in addition to forming the sealing layer 6 under a nitrogen atmosphere. The sealing member having transparency can be formed from glass, plastic, or the like, and preferably has a concave shape.

An embodiment of the present invention relates specifically to the light-emitting element layer 5 of the configuration of the display device described above.

### Configuration of Light-Emitting Element Layer

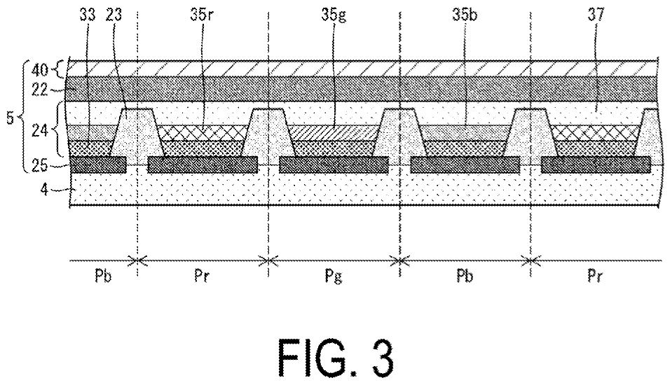

FIG. 3 is a cross-sectional view illustrating a schematic configuration of the light-emitting element layer 5 in the display device 2 according to the first embodiment of the present invention.

As illustrated in FIG. 3, the display device according to the first embodiment of the present invention includes a red pixel Pr (light-emitting element) including a red pixel electrode PEr, a green pixel Pg (light-emitting element) including a green pixel electrode PEg, and a blue pixel Pb (light-emitting element) including a blue pixel electrode PEb.

The light-emitting element layer 5 according to the first embodiment of the present invention includes the cathodes 25 as the green pixel electrode PEg, the blue pixel electrode PEb, and the red pixel electrode PEr. The cathode 25 is a reflective electrode.

The light-emitting element layer 5 includes the edge cover 23 having an insulating property and covering the edges of the cathodes 25. The edge cover 23 is a light-blocking body that blocks light among the red pixel Pr, the green pixel Pg, and the blue pixel Pb.

The light-emitting element layer 5 includes the active layer 24 that is an ElectroLuminescence (EL) layer provided as an upper layer than the edge cover 23.

The active layer 24 includes an electron transport layer 33. The electron transport layer 33 is formed covering the cathode 25. The electron transport layer 33 may be a single layer structure or multilayer structure. The electron transport layer 33 may be separately or commonly formed for the red pixel Pr, the green pixel Pg, and the blue pixel Pb. In a case of being separately formed, the electron transport layer 33 provided in the red pixel Pr, the electron transport layer 33 provided in the green pixel Pg, and the electron transport layer 33 provided in the blue pixel Pb may have different film thicknesses and/or compositions from each other. The active layer 24 may include an electron injection layer formed between the electron transport layer 33 and the cathode 25.

The active layer 24 includes a red light-emitting layer 35r formed in an island shape in the red pixel Pr. The red light-emitting layer 35r includes a plurality of red quantum dots that emit red light. A peak wavelength of the light emission spectrum due to the electroluminescence of the red quantum dots is equal to or greater than 600 nm and equal to or less than 780 nm. Note that, in order to improve the color reproduction range of the display device, the peak wavelength of the light emission spectrum of the red pixel Pr is preferably equal to or greater than 620 nm and equal to or less than 650 nm.

The active layer 24 includes a green light-emitting layer 35g formed in an island shape in the green pixel Pg. The green light-emitting layer 35g includes a plurality of green quantum dots that emit green light. A peak wavelength of the light emission spectrum due to the electroluminescence of the green quantum dots is equal to or greater than 500 nm and equal to or less than 600 nm. Note that, in order to improve the color reproduction range of the display device, the peak wavelength of the light emission spectrum of the green pixel Pg is preferably equal to or greater than 520 nm and equal to or less than 540 nm.

The active layer 24 includes the blue light-emitting layer 35b formed in an island shape in the blue pixel Pb. The blue light-emitting layer 35b includes a plurality of blue quantum dots that emit blue light. A peak wavelength of the light emission spectrum due to the electroluminescence of the blue quantum dots is equal to or greater than 400 nm and equal to or less than 500 nm. Note that, in order to improve the color reproduction range of the display device, the peak wavelength of the light emission spectrum of the blue pixel Pb is preferably equal to or greater than 440 nm and equal to or less than 460 nm.

The active layer 24 includes a hole transport layer 37 formed in a solid-like shape. The hole transport layer 37 is formed in the solid-like shape so as to cover the green light-emitting layer 35g, the red light-emitting layer 35r, and the blue light-emitting layer 35b. The hole transport layer 37 is not limited thereto, and the hole transport layer 37 may be formed integrally with the anode 22 or may be formed in an island shape so as to individually cover each of the green light-emitting layer 35g, the red light-emitting layer 35r, and the blue light-emitting layer 35b. In addition, the hole transport layer 37 may be a single layer structure or a layered structure. The active layer 24 may include a hole injection layer formed between the hole transport layer 37 and the anode 22.

The light-emitting element layer 5 includes the anode 22 provided as an upper layer than the active layer 24. The anode 22 is a transparent electrode. The anode 22 is integrally formed across the red pixel Pr, the green pixel Pg, and the blue pixel Pb. The anode 22 is not limited thereto, and may be separately formed for each of the red pixel Pr, the green pixel Pg, and the blue pixel Pb.

The light-emitting element layer 5 includes the selectively reflective layer 40 that is an upper layer than the anode 22. The selectively reflective layer 40 is provided at an opposite side to the red light-emitting layer 35r, the green light-emitting layer 35g, and the blue light-emitting layer 35b with respect to the anode 22. The selectively reflective layer 40 is integrally formed across the red pixel Pr, the green pixel Pg, and the blue pixel Pb. The selectively reflective layer 40 has a reflection band having a higher reflectivity than those of other bands. The selectively reflective layer 40 is configured so that the absorption and re-emission of light of the blue quantum dots occur when light having a wavelength included in the reflection band of the selectively reflective layer 40 is incident on the blue light-emitting layer 35b.

### Reflection and Transmission in Light-Emitting Element Layer

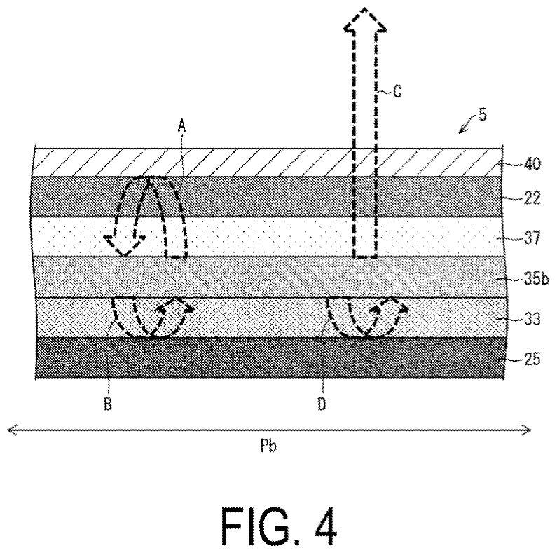

The reflection and transmission in the light-emitting element layer 5 in the blue pixel Pb will be described below with reference to FIG. 4.

FIG. 4 is a schematic cross-sectional view illustrating the reflection and transmission in the light-emitting element layer 5 in the blue pixel Pb illustrated in FIG. 3.

As illustrated by an arrow A in FIG. 4, among light emitted from the blue light-emitting layer 35b to the anode 22 side, light having a wavelength included in the reflection band of the selectively reflective layer 40 is reflected by the selectively reflective layer 40. On the other hand, as illustrated by an arrow C in FIG. 4, among light emitted from the blue light-emitting layer 35b to the anode 22 side, light having a wavelength not included in the reflection band of the selectively reflective layer 40 is transmitted through the selectively reflective layer 40.

As illustrated by arrows B and D in FIG. 4, among light emitted from the blue light-emitting layer 35b to the cathode 25 side is reflected by the cathode 25 regardless of a wavelength that the light has.

Thus, the light having a wavelength included in the reflection band of the selectively reflective layer 40 (hereinafter, referred to as “light within the reflection band”) reciprocates between the cathode 25 and the selectively reflective layer 40, and repeatedly passes through the blue light-emitting layer 35b. The light within the reflection band is absorbed into the blue quantum dots inside the blue light-emitting layer 40 during repeated passing. The blue quantum dots that has absorbed the light re-emits light having a wavelength equal to or lower than the wavelength of the absorbed light. Thus, finally, the light within the reflection band is converted into light having a wavelength that is longer than a wavelength at a long wavelength end of the reflection band of the selectively reflective layer 40 due to the absorption and re-emission of light by the blue quantum dots. The light having the wavelength that is longer than the wavelength at the long wavelength end of the reflection band is light having a wavelength not included in the reflection band of the selectively reflective layer 40 (hereinafter, referred to as “light outside the reflection band”).

Then, the light having the wavelength outside the reflection band passes through the selectively reflective layer 40 and is emitted outside the light-emitting element layer 5.

### Reflection Band of Selectively Reflective Layer

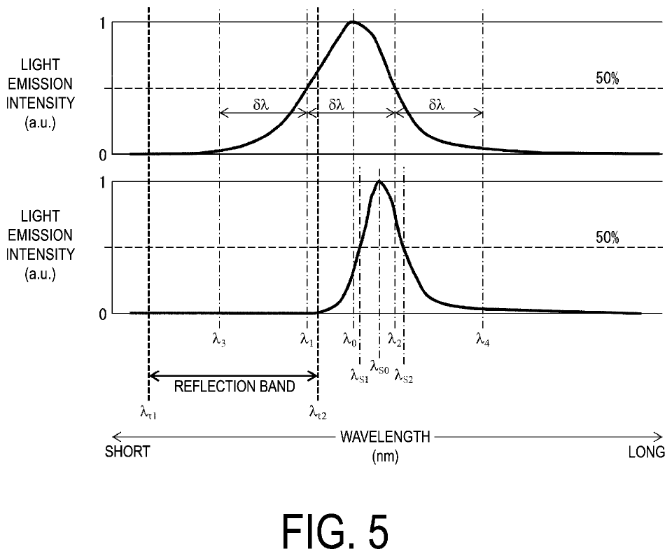

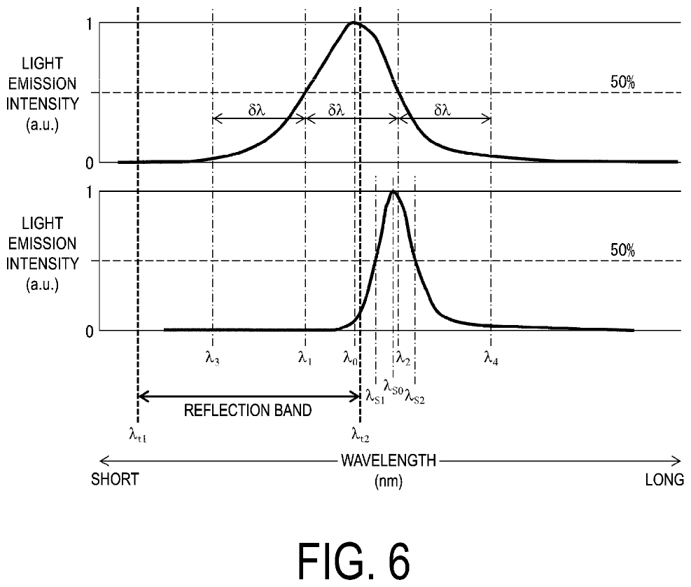

FIG. 5 is a diagram illustrating, on the upper side, a graph showing a light emission spectrum due to electroluminescence of a light-emitting element layer according to a comparative example in which the selectively reflective layer 40 is removed from the light-emitting element layer 5 illustrated in FIG. 4, and illustrating, on the lower side, a graph showing a light emission spectrum due to electroluminescence from the example of the light-emitting element layer 5 illustrated in FIG. 4. FIG. 6 is a diagram illustrating, on the upper side, a graph showing a light emission spectrum due to electroluminescence of the light-emitting element layer according to the comparative example in which the selectively reflective layer 40 is removed from the light-emitting element layer 5 illustrated in FIG. 4, and illustrating, on the lower side, a graph showing a light emission spectrum due to electroluminescence from another example of the light-emitting element layer 5 illustrated in FIG. 4. In FIG. 5 and FIG. 6, a vertical axis indicates a light emission intensity (without a unit) standardized with a light emission intensity at each peak wavelength as one unit, and a horizontal axis indicates a wavelength (nm).

As described above, an absorption rate in the reflection band of the light-emitting element layer 5 excluding the blue light-emitting layer 35b is so small as to be negligible. Also, an absorption rate of the light-emitting element layer 5 outside the reflection band is so small as to be negligible. Thus, the light emission spectrum due to the electroluminescence of the light-emitting element layer according to the comparative example (on the upper side in FIG. 5 and FIG. 6) is substantially the same as the light emission spectrum due to the electroluminescence of the blue quantum dots.

The spectra shown in FIG. 5 and FIG. 6 are defined as follows.
λ₀: A peak wavelength of the light emission spectrum due to the electroluminescence of the blue quantum dots.
δλ: A full width at half maximum of the light emission spectrum due to the electroluminescence of the blue quantum dots.
λ₁: A wavelength at which the light emission spectrum due to the electroluminescence of the blue quantum dots has a half value of a peak value of the light emission spectrum due to the electroluminescence of the blue quantum dots at the shorter wavelength side than the peak wavelength λ₀.
λ₂: A wavelength at which the light emission spectrum due to the electroluminescence of the blue quantum dots has the half value of the peak value of the light emission spectrum due to the electroluminescence of the blue quantum dots at the longer wavelength side than the peak wavelength λ₀.
λ₃: A wavelength that is shorter than the wavelength λ₁ by δλ.
λ₄: A wavelength that is longer than the wavelength λ₁ by δλ.
λ_{S0}: A peak wavelength of the light emission spectrum of the light-emitting element layer 5.
λ_{S1}: A wavelength at which the light emission spectrum of the light-emitting element layer 5 has a half value of a peak value of the light emission spectrum of the light-emitting element layer 5 at the shorter wavelength side than the peak wavelength λ_{S0}.
λ_{S2}: A wavelength at which the light emission spectrum of the light-emitting element layer 5 has the half value of the peak value of the light emission spectrum of the light-emitting element layer 5 at the longer wavelength side than the peak wavelength λ_{S0}.
λₜ₁: A wavelength at a short wavelength end in the reflection band of the selectively reflective layer 40.
λₜ₂: A wavelength at a long wavelength end in the reflection band of the selectively reflective layer 40.

As described above, light within the reflection band is converted into light having a wavelength that is longer than the wavelength at the long wavelength end in the reflection band, and then emitted out of the light-emitting element layer 5. Thus, as shown in FIG. 5 and FIG. 6, the light emission spectrum of the light-emitting element layer 5 is made narrower in bandwidth at the longer wavelength side than the light emission spectrum due to the electroluminescence of the blue quantum dots.

In order to facilitate such narrowing in bandwidth, it is preferable that the probability of the occurrence of the absorption and re-emission of light by the blue quantum dots be high. Thus, it is preferable that the wavelength λₜ₂ at the long wavelength end in the reflection band of the selectively reflective layer 40 be close to the peak wavelength λ₀ of the light emission spectrum due to the electroluminescence of the blue quantum dots. Specifically, the wavelength λ^{t2} at the long wavelength end in the reflection band of the selectively reflective layer 40 is (i) preferably longer than the wavelength λ₁ having the half value of the peak value of the light emission spectrum due to the electroluminescence of the blue quantum dots at the shorter wavelength side than the peak wavelength λ₀ of the light emission spectrum due to the electroluminescence of the blue quantum dots, and (ii) preferably shorter than the wavelength λ₂ having the half value of the peak value of the light emission spectrum due to the electroluminescence of the blue quantum dots at the longer wavelength side than the peak wavelength λ₀ of the light emission spectrum due to the electroluminescence of the blue quantum dots. In other words, it is preferable to satisfy λ₁<λₜ₂<λ₂. When the relationships of λ₁=λ₀−δλ/2, and λ₂=λ₀+δλ/2 hold, it is preferable to satisfy λ₀−δλ/2<λₜ₂<λ₀+δλ/2.

Additionally, in order to facilitate such narrowing in bandwidth, a range in which the reflection band of the selectively reflective layer 40 overlaps the tail at the shorter wavelength side of the light emission spectrum due to the electroluminescence of the blue quantum dots is preferably wide. Specifically, the wavelength λₜ₁ at the short wavelength end in the reflection band of the selectively reflective layer 40 is preferably equivalent to or shorter than the wavelength λ₃. Thus, it is preferable to satisfy λₜ₁≤λ₃.

Furthermore, in order to facilitate such narrowing in bandwidth, it is preferable that the reflectivity of the selectively reflective layer 40 in the reflection band (being equal to or greater than λₜ₁ and equal to or less than λₜ₂) of the selectively reflective layer 40 be high. Specifically, the reflectivity is preferably equal to or greater than 95%. At the same time, it is preferable that an absorption rate of the selectively reflective layer 40 in the peripheral band of the peak wavelength λ₀ of the light emission spectrum due to the electroluminescence of the blue quantum dots be low. Specifically, the absorption rate in the wavelength range being equal to or greater than the wavelength λ₃ and equal to or less than the wavelength λ₄ is preferably equal to or less than 1%. Further, the selectively reflective layer 40 is formed across the red pixel Pr and the green pixel Pg. Thus, it is preferable that an absorption rate of the selectively reflective layer 40 in a peripheral band of a peak wavelength of a light emission spectrum due to electroluminescence of each of the red quantum dots and the green quantum dots be also low.

Furthermore, as shown in FIG. 6, the peak wavelength λ_{S0} of the light emission spectrum of the light-emitting element layer 5 can be shifted to a longer wavelength side than the peak wavelength λ₀ of the light emission spectrum due to the electroluminescence of the blue quantum dots. Such a shift to the longer wavelength side may be achieved by the fact that the wavelength λₜ₂ at the long wavelength end in the reflection band of the selectively reflective layer 40 is longer than the peak wavelength λ₀ of the light emission spectrum due to the electroluminescence of the blue quantum dots. Thus, it is preferable to satisfy λ₀<λₜ₂<λ₂, that is, λ₀<λₜ₂<λ₀+δλ/2.

Such a shift to the longer wavelength side has a beneficial effect when the peak wavelength of the blue quantum dots is too short, compared to the peak wavelength of the blue pixel Pb to be targeted (for example, equal to or greater than 440 nm and equal to or greater than 460 nm). The shift to the longer wavelength side allows an actual peak wavelength of the blue pixel Pb to be closer to the peak wavelength to be targeted from the peak wavelength of the blue quantum dots. This can improve the color reproduction range of the display device.

### Dielectric Multilayer Film

The selectively reflective layer 40 may have any configuration as long as the selectively reflective layer 40 functions as a bandpass filter having a high reflectivity in the reflection band as described above. The selectively reflective layer 40 is, for example, a dielectric multilayer film.

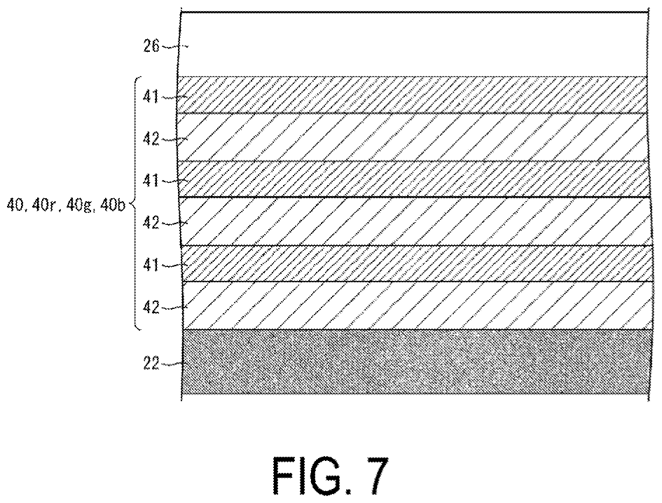

FIG. 7 is a cross-sectional view illustrating a schematic configuration of an example in a case where the selectively reflective layer 40 illustrated in FIG. 3 is a dielectric multilayer film.

As illustrated in FIG. 7, when the selectively reflective layer 40 is a dielectric multilayer film, the selectively reflective layer 40 is preferably a layered body in which a first dielectric film 41 and a second dielectric film 42 having different dielectric constants from each other are alternately layered. Note that the first dielectric film 41 has a higher refractive index than that of the second dielectric film, and a dielectric film closest to the anode 22 is the second dielectric film 42.

A thickness of the first dielectric film 41 is preferably equal to or greater than 189 nm and equal to or less than 246 nm, and a thickness of the second dielectric film 42 is preferably equal to or greater than 291 nm and equal to or less than 378 nm. A sum of the number of layers of the first dielectric film 41 and the number of layers of the second dielectric film 42 that are included in the selectively reflective layer 40 is equal to or greater than three.

The first dielectric film 41 preferably has a vacuum dielectric constant being equal to or greater than 4.8 and equal to or less than 6.0. For example, the first dielectric film 41 is preferably configured to include at least one of titanium oxide, niobium pentoxide, and tantalum pentoxide.

The second dielectric film 42 preferably has a vacuum dielectric constant being equal to or greater than 1.9 and equal to or less than 3.3. For example, the second dielectric film 42 is preferably configured to include at least one of silicon oxide, magnesium fluoride, and aluminum oxide.

### First Modified Example

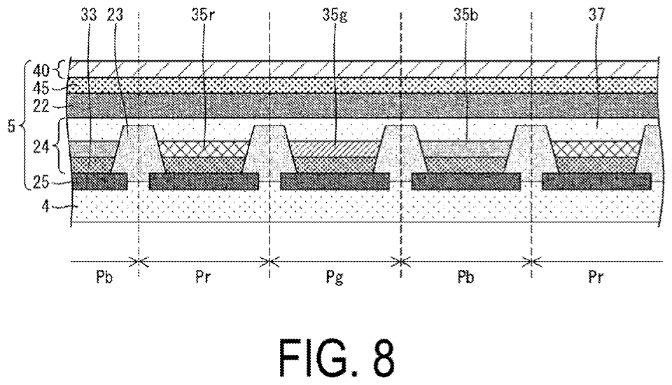

FIG. 8 is a cross-sectional view illustrating a schematic configuration of a light-emitting element layer 5 according to a modified example of the first embodiment.

As illustrated in FIG. 8, the light-emitting element layer 5 may further include a photoluminescence layer 45 formed between the selectively reflective layer 40 and the anode 22. The photoluminescence layer 45 may be formed across the red pixel Pr, the green pixel Pg, and the blue pixel Pb, as illustrated in FIG. 8, but may be formed only in the blue pixel Pb although not illustrated.

The photoluminescence layer 45 is configured to emit light with the same color as light emitted by the blue light-emitting layer 35b by being excited by the light emitted by the blue light-emitting layer 35b. The wavelength of the light emitted by the photoluminescence layer 45 is shorter than the wavelength of the light emitted by the blue light-emitting layer 35b.

The light emitted by the photoluminescence layer 45 is preferably transmitted through the selectively reflective layer 40. Thus, it is preferable that a peak wavelength λᵤ₀ of a light emission spectrum of the photoluminescence layer 45 be longer than the wavelength λₜ₂ at the long wavelength end in the reflection band of the selectively reflective layer 40. Furthermore, a wavelength λ_{U1} at which the light emission spectrum of the photoluminescence layer 45 has a half value of a peak value of the light emission spectrum of the photoluminescence layer 45 at the shorter wavelength side than the peak wavelength λᵤ₀ is preferably longer than the wavelength λₜ₂ at the long wavelength end in the reflection band of the selectively reflective layer 40. Thus, it is preferable to satisfy λₜ₂<λ_{U0}, and is more preferable to satisfy λₜ₂<λ_{U1}.

This modification is applicable to second to fourth embodiments, which will be described below.

### Second Modified Example

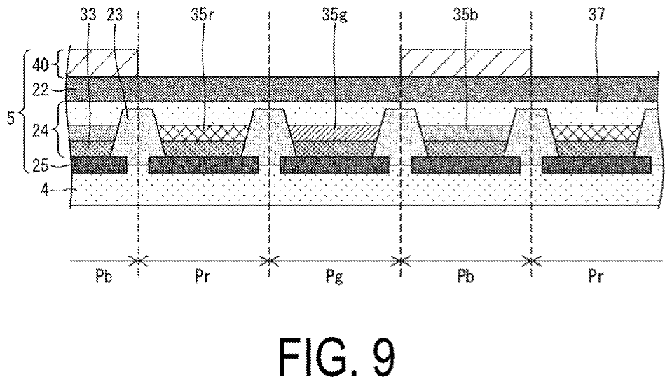

FIG. 9 is a cross-sectional view illustrating a schematic configuration of a light-emitting element layer 5 according to another modified example of the first embodiment.

As illustrated in FIG. 9, the selectively reflective layer 40 may be formed only in the blue pixel Pb.

### Second Embodiment

A display device 2 according to a second embodiment of the present invention is a one-sided light-emitting type as illustrated in FIG. 2.

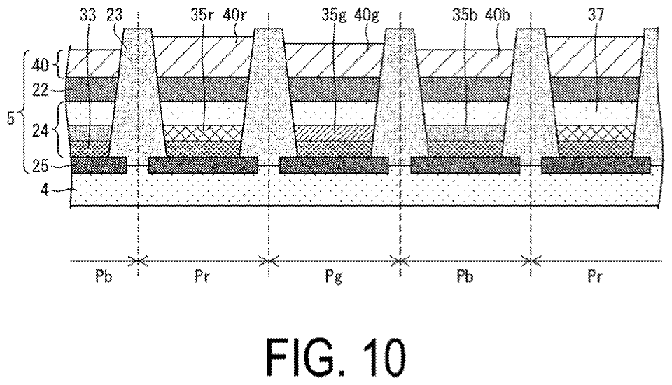

FIG. 10 is a cross-sectional view illustrating a schematic configuration of a light-emitting element layer 5 in the display device according to the second embodiment of the present invention.

As illustrated in FIG. 10, the light-emitting element layer 5 according to the second embodiment has the same configuration as the light-emitting element layer 5 according to the first embodiment described above, except for the following two points. One point thereof is that the selectively reflective layer 40 is constituted by a red selectively reflective layer 40r formed only in the red pixel Pr, a green selectively reflective layer 40g formed only in the green pixel Pg, and a blue selectively reflective layer 40b formed only in the blue pixel Pb. The other point is that the edge cover 23 is highly formed such that the upper face of the edge cover 23 has a height being higher than or equal to those of the upper surfaces of the red selectively reflective layer 40r, the green selectively reflective layer 40g, and the blue selectively reflective layer 40b.

The red selectively reflective layer 40r is configured such that the absorption and re-emission of light of the red quantum dots occur when light having a wavelength included in the reflection band of the red selectively reflective layer 40r is incident on the red light-emitting layer 35r. Thus, similarly to the selectively reflective layer 40 for the blue pixel Pb in the first embodiment described above, the red selectively reflective layer 40r according to the second embodiment causes narrowing in bandwidth of the light emission spectrum of the red pixel Pr.

A wavelength at the short wavelength end in the reflection band of the red selectively reflective layer 40r preferably satisfies a condition that the wavelength λₜ₁ at the short wavelength end in the reflection band of the selectively reflective layer 40 according to the first embodiment described above preferably satisfies for the blue quantum dots, with the condition for the blue quantum dots read as the condition for the red quantum dots. A wavelength at the long wavelength end in the reflection band of the red selectively reflective layer 40r preferably satisfies a condition that the wavelength λₜ₂ at the long wavelength end in the reflection band of the selectively reflective layer 40 according to the first embodiment described above preferably satisfies for the blue quantum dots, with the condition for the blue quantum dots read as the condition for the red quantum dots.

The red selectively reflective layer 40r may have any configuration as long as the red selectively reflective layer 40r functions as a bandpass filter having a high reflectivity in the reflection band as described above, or may be a dielectric multilayer film. For example, when the red selectively reflective layer 40r is the dielectric multilayer film illustrated in FIG. 7, a thickness of the first dielectric film 41 is preferably equal to or greater than 126 nm and equal to or less than 157 nm, and a thickness of the second dielectric film 42 is preferably equal to or greater than 194 nm and equal to or less than 242 nm.

The green selectively reflective layer 40g is configured such that the absorption and re-emission of light of the green quantum dots occur when light having a wavelength included in the reflection band of the green selectively reflective layer 40g is incident on the green light-emitting layer 35g. Thus, similarly to the selectively reflective layer 40 for the blue pixel Pb in the first embodiment described above, the green selectively reflective layer 40g according to the second embodiment causes narrowing in bandwidth of the light emission spectrum of the green pixel Pg.

A wavelength at the short wavelength end in the reflection band of the green selectively reflective layer 40g preferably satisfies a condition that the wavelength λₜ₁ at the short wavelength end in the reflection band of the selectively reflective layer 40 according to the first embodiment described above preferably satisfies for the blue quantum dots, with the condition for the blue quantum dots read as the condition for the green quantum dots. A wavelength at the long wavelength end in the reflection band of the green selectively reflective layer 40g preferably satisfies a condition that the wavelength λₜ₂ at the long wavelength end in the reflection band of the selectively reflective layer 40 according to the first embodiment described above preferably satisfies for the blue quantum dots, with the condition for the blue quantum dots read as the condition for the green quantum dots.

The green selectively reflective layer 40g may be any configuration as long as the green selectively reflective layer functions as a bandpass filter having a high reflectivity in the reflection band as described above, or may be a dielectric multilayer film.

For example, when the green selectively reflective layer 40g is the dielectric multilayer film illustrated in FIG. 7, a thickness of the first dielectric film 41 is preferably equal to or greater than 157 nm and equal to or less than 189 nm, and a thickness of the second dielectric film 42 is preferably equal to or greater than 242 nm and equal to or less than 291 nm.

The blue selectively reflective layer 40b is configured such that the absorption and re-emission of light of the blue quantum dots occur when light having a wavelength included in the reflection band of the blue selectively reflective layer 40b is incident on the blue light-emitting layer 35b. Thus, similarly to the selectively reflective layer 40 for the blue pixel Pb in the first embodiment described above, the blue selectively reflective layer 40b according to the second embodiment causes narrowing in bandwidth of the light emission spectrum of the blue pixel Pb.

The wavelength at the short wavelength end in the reflection band of the blue selectively reflective layer 40b preferably satisfies, in a similar manner, the condition that the wavelength λₜ₁ at the short wavelength end in the reflection band of the selectively reflective layer 40 according to the first embodiment described above preferably satisfies for the blue quantum dots. The wavelength at the long wavelength end in the reflection band of the blue selectively reflective layer 40b preferably satisfies, in a similar manner, the condition that the wavelength λₜ₂ at the long wavelength end in the reflection band of the selectively reflective layer 40 according to the first embodiment described above preferably satisfies for the blue quantum dots.

The blue selectively reflective layer 40b may be any configuration as long as the blue selectively reflective layer 40b functions as a bandpass filter having a high reflectivity in the reflection band as described above, or may be a dielectric multilayer film. For example, when the blue selectively reflective layer 40b is the dielectric multilayer film illustrated in FIG. 7, a thickness of the first dielectric film 41 is equal to or greater than 189 nm and equal to or less than 246 nm, and a thickness of the second dielectric film 42 is preferably equal to or greater than 291 nm and equal to or less than 378 nm.

As the height of the edge cover 23 increases, the anode 22 is individually formed for each of the red pixel Pr, the green pixel Pg, and the blue pixel Pb. Additionally, the anode 22 of the red pixel Pr is surrounded by the edge cover 23, and the anode 22 of the green pixel Pg and the anode 22 of the blue pixel Pb are also surrounded by the edge cover 23. Thus, light reflected by the selectively reflective layer 40 is prevented from leaking through the cathode 25 to the adjacent pixels. Additionally, the red selectively reflective layer 40r of the red pixel Pr is surrounded by the edge cover 23, and the green selectively reflective layer 40g of the green pixel Pg and the blue selectively reflective layer 40b of the blue pixel Pb are also surrounded by the edge cover 23. Thus, light reflected by the selectively reflective layer 40 is prevented from leaking to the adjacent pixels through the selectively reflective layer 40.

### Third Modified Example

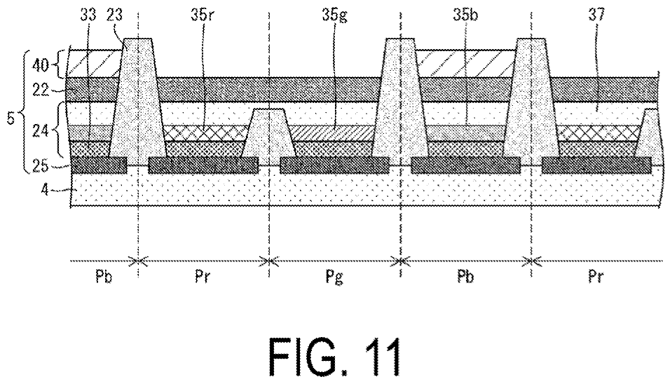

FIG. 11 is a cross-sectional view illustrating a schematic configuration of the light-emitting element layer 5 according to a modified example of the second embodiment.

As illustrated in FIG. 11, only the blue selectively reflective layer 40b may be formed, and the red selectively reflective layer 40r and the green selectively reflective layer 40g do not need to be formed. In this case, the edge cover 23 positioned between the red pixel Pr and the green pixel Pg may be formed low in height such that the upper face of the edge cover 23 has a height being equal to or lower than the lower face of the cathode 25.

### Third Embodiment

The display device 2 according to a third embodiment of the present invention is a both-sided light-emitting type.

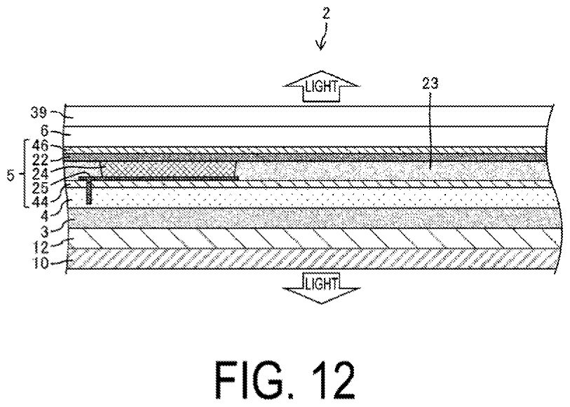

FIG. 12 is a schematic cross-sectional view illustrating another example of a configuration of the display region of the display device 2.

Although the display device of the one-sided light-emitting type has been described in the first embodiment described above, when a display device of a both-sided light-emitting type is manufactured, both the cathode 25 (first transparent electrode) and the anode 22 (second transparent electrode) are transparent electrodes, and the lower face film 10 and the resin layer 12 have transparency. In addition, as illustrated in FIG. 12, the light-emitting element layer 5 includes the cathode 25, the edge cover 23, the active layer 24, and the anode 22, and further includes a first selectively reflective layer 44 provided as a lower layer than the cathode 25 and a second selectively reflective layer 46 provided as an upper layer than the anode 22. The first selectively reflective layer 44 and the second selectively reflective layer 46 have a reflection band having a higher reflectivity than those of other bands. Details will be described below.

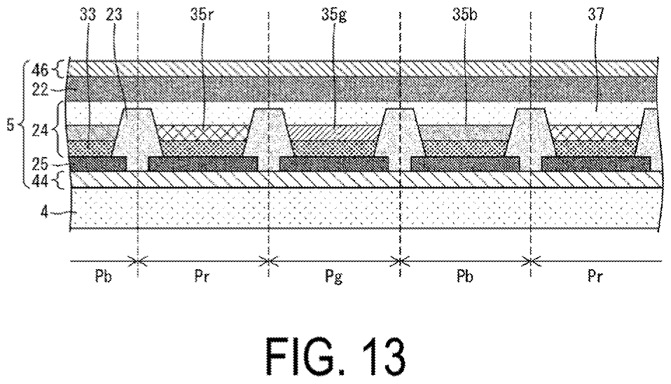

FIG. 13 is a cross-sectional view illustrating a schematic configuration of the light-emitting element layer 5 in the display device according to the third embodiment of the present invention.

As illustrated in FIG. 13, the light-emitting element layer 5 according to the third embodiment has the same configuration as the light-emitting element layer 5 according to the first embodiment described above, except for the following two points. One point is that both the cathode 25 (first transparent electrode) and the anode 22 (second transparent electrode) are transparent electrodes. The other point is that the first selectively reflective layer 44 provided as a lower layer than the cathode 25 and the second selectively reflective layer 46 provided as an upper layer than the anode 22 are included.

The optical characteristics of the first selectively reflective layer 44 and the second selectively reflective layer 46 are preferably equivalent so that the light-emission characteristics of the display device are equivalent on both sides. The optical characteristics include the wavelength at the short wavelength end in the reflection band and the wavelength at the long wavelength end.

The first selectively reflective layer 44 is provided at the side opposite to the red light-emitting layer 35r, the green light-emitting layer 35g, and the blue light-emitting layer 35b with respect to the cathode 25. The first selectively reflective layer 44 is integrally formed across the red pixel Pr, the green pixel Pg, and the blue pixel Pb. The first selectively reflective layer 44 has a reflection band having a higher reflectivity than those of other bands. The first selectively reflective layer 44 is configured so that the absorption and re-emission of light of the blue quantum dots occur when light having a wavelength included in the reflection band of the first selectively reflective layer 44 is incident on the blue light-emitting layer 35b.

The second selectively reflective layer 46 is provided at the opposite side to the red light-emitting layer 35r, the green light-emitting layer 35g, and the blue light-emitting layer 35b with respect to the anode 22. The second selectively reflective layer 46 is integrally formed across the red pixel Pr, the green pixel Pg, and the blue pixel Pb. The second selectively reflective layer 46 has a reflection band having a higher reflectivity than those of other bands. The second selectively reflective layer 46 is configured so that the absorption and re-emission of light of the blue quantum dots occur when light having a wavelength included in the reflection band of the second selectively reflective layer 46 is incident on the blue light-emitting layer 35b.

Thus, similarly to the selectively reflective layer 40 for the blue pixel Pb in the first embodiment described above, the first selectively reflective layer 44 and the second selectively reflective layer 46 according to the third embodiment cause narrowing in bandwidth of the light emission spectrum of the blue pixel Pb.

A wavelength at the short wavelength end in the reflection band of the first selectively reflective layer 44 preferably satisfies, in a similar manner, the condition that the wavelength λₜ₁ at the short wavelength end in the reflection band of the selectively reflective layer 40 according to the first embodiment described above preferably satisfies for the blue quantum dots. A wavelength at the long wavelength end in the reflection band of the first selectively reflective layer 44 preferably satisfies, in a similar manner, the condition that the wavelength λₜ₂ at the long wavelength end in the reflection band of the selectively reflective layer 40 according to the first embodiment described above preferably satisfies for the blue quantum dots.

A wavelength at the short wavelength end in the reflection band of the second selectively reflective layer 46 preferably satisfies, in a similar manner, the condition that the wavelength λₜ₁ at the short wavelength end in the reflection band of the selectively reflective layer 40 according to the first embodiment described above preferably satisfies for the blue quantum dots. A wavelength at the long wavelength end in the reflection band of the second selectively reflective layer 46 preferably satisfies, in a similar manner, the condition that the wavelength λₜ₂ at the long wavelength end in the reflection band of the selectively reflective layer 40 according to the first embodiment described above preferably satisfies for the blue quantum dots.

The first selectively reflective layer 44 and the second selectively reflective layer 46 may have any configuration as long as the first selectively reflective layer 44 and the second selectively reflective layer 46 function as a bandpass filter having a high reflectivity in the reflection band as described above, or may be dielectric multilayer films.

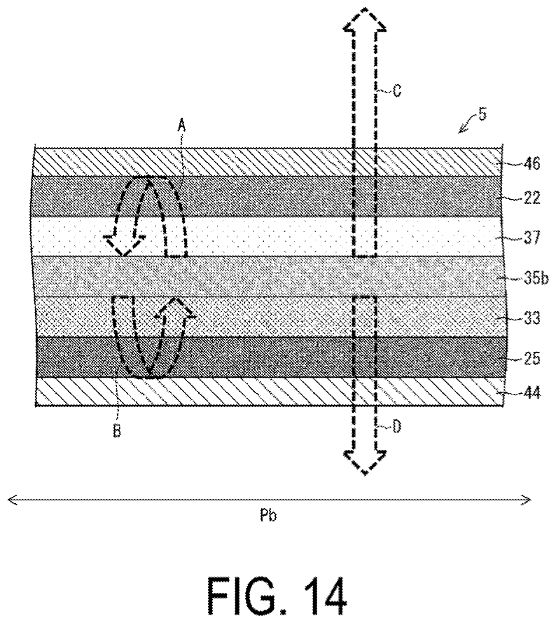

Reflection and Transmission in Light-Emitting Element Layer Hereinafter, when the optical characteristics of the first selectively reflective layer 44 and the second selectively reflective layer 46 are identical, the reflection and transmission in the light-emitting element layer 5 in the blue pixel Pb will be described with reference to FIG. 14.

FIG. 14 is a schematic cross-sectional view illustrating the reflection and transmission in the light-emitting element layer 5 in the blue pixel Pb illustrated in FIG. 13.

As indicated by an arrow A in FIG. 14, light having a wavelength included in the reflection band of the second selectively reflective layer 46, of light emitted from the blue light-emitting layer 35b to the anode 22 side, is reflected by the second selectively reflective layer 46. On the other hand, as indicated by an arrow C in FIG. 4, light having a wavelength that is not included in the reflection band of the second selectively reflective layer 46, of the light emitted from the blue light-emitting layer 35b to the anode 22 side, is transmitted through the second selectively reflective layer 46.

As indicated by an arrow B in FIG. 14, light having a wavelength included in the reflection band of the first selectively reflective layer 44, of light emitted from the blue light-emitting layer 35b to the cathode 25 side, is reflected by the first selectively reflective layer 44. On the other hand, as indicated by an arrow D in FIG. 4, light having a wavelength that is not included in the reflection band of the first selectively reflective layer 44, of the light emitted from the blue light-emitting layer 35b to the cathode 25 side, is transmitted through the first selectively reflective layer 44.

Thus, light having a wavelength included in the reflection bands of the first selectively reflective layer 44 and the second selectively reflective layer 46 (hereinafter, referred to as light “in the reflection bands”) reciprocates between the first selectively reflective layer 44 and the second selectively reflective layer 46, and repeatedly passes through the blue light-emitting layer 35b. The light having the wavelength in the reflection bands is absorbed into the blue quantum dots provided thereinside during repeated passing. The blue quantum dots into which the light has been absorbed re-emits light having a wavelength equal to or less than the wavelength of the absorbed light. Thus, finally, the light having the wavelength in the reflection band is converted into light having a wavelength being longer than that at the long wavelength end in the reflection band through the absorption and re-emission of light by the blue quantum dots. The light having the wavelength being longer than that at the long wavelength end in the reflection band is light having a wavelength that is not included in the reflection bands of the first selectively reflective layer 44 and the second selectively reflective layer 46 (hereinafter, referred to as “light outside the reflection bands”).

Then, the light having the wavelength outside the reflection bands passes through the selectively reflective layer 40 and is emitted outside the light-emitting element layer 5.

### Fourth Embodiment

A display device 2 according to a fourth embodiment of the present invention is a both-sided light-emitting type as illustrated in FIG. 12.

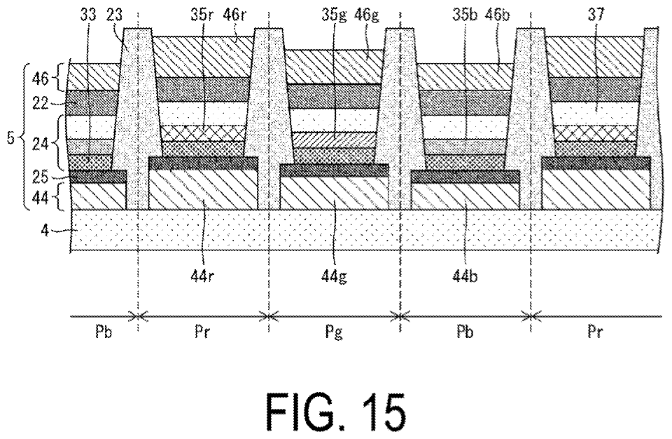

FIG. 15 is a cross-sectional view illustrating a schematic configuration of a light-emitting element layer 5 in the display device according to the fourth embodiment of the present invention.

As illustrated in FIG. 13, the light-emitting element layer 5 according to the fourth embodiment has the same configuration as the light-emitting element layer 5 according to the second embodiment, except for the following two points. One point is that both the cathode 25 (first transparent electrode) and the anode 22 (second transparent electrode) are transparent electrodes. The other point is that the first selectively reflective layer 44 provided as a lower layer than the cathode 25 and the second selectively reflective layer 46 provided as an upper layer than the anode 22 are included.

The first selectively reflective layer 44 includes a red first selectively reflective layer 44r formed only in the red pixel Pr, a green first selectively reflective layer 44g formed only in the green pixel Pg, and a blue first selectively reflective layer 44b formed only in the blue pixel Pb.

The second selectively reflective layer 46 includes a red second selectively reflective layer 46r formed only in the red pixel Pr, a green second selectively reflective layer 46g formed only in the green pixel Pg, and a blue second selectively reflective layer 46b formed only in the blue pixel Pb.

The red first selectively reflective layer 44r has a reflection band having a higher reflectivity than those of other bands. The red first selectively reflective layer 44r is configured so that the absorption and re-emission of light of the red quantum dots occur when light having a wavelength included in the reflection band of the red first selectively reflective layer 44r is incident on the red light-emitting layer 35r. The red second selectively reflective layer 46r has a reflection band having a higher reflectivity than those of other bands. The red second selectively reflective layer 46r is configured so that the absorption and re-emission of light of the red quantum dots occur when light having a wavelength included in the reflection band of the red second selectively reflective layer 46r is incident on the red light-emitting layer 35r. Thus, similarly to the first selectively reflective layer 44 and the second selectively reflective layer 46 for the blue pixel Pb in the third embodiment, the red first selectively reflective layer 44r and the red second selectively reflective layer 46r according to the fourth embodiment cause narrowing in bandwidth of the light emission spectrum of the red pixel Pr.

The green first selectively reflective layer 44g has a reflection band having a higher reflectivity than those of other bands. The green first selectively reflective layer 44g is configured so that the absorption and re-emission of light of the green quantum dots occur when light having a wavelength included in the reflection band of the green first selectively reflective layer 44g is incident on the green light-emitting layer 35g. The green second selectively reflective layer 46g has a reflection band having a higher reflectivity than those of other bands. The green second selectively reflective layer 46g is configured so that the absorption and re-emission of light of the green quantum dots occur when light having a wavelength included in the reflection band of the green second selectively reflective layer 46g is incident on the green light-emitting layer 35g. Thus, similarly to the first selectively reflective layer 44 and the second selectively reflective layer 46 for the blue pixel Pb in the third embodiment, the green first selectively reflective layer 44g and the green second selectively reflective layer 46g according to the fourth embodiment cause narrowing in bandwidth of the light emission spectrum of the green pixel Pg.

The blue first selectively reflective layer 44b has a reflection band having a higher reflectivity than those of other bands. The blue first selectively reflective layer 44b is configured so that the absorption and re-emission of light of the blue quantum dots occur when light having a wavelength included in the reflection band of the blue first selectively reflective layer 44b is incident on the blue light-emitting layer 35b. The blue second selectively reflective layer 46b has a reflection band having a higher reflectivity than those of other bands. The blue second selectively reflective layer 46b is configured so that the absorption and re-emission of light of the blue quantum dots occur when light having a wavelength included in the reflection band of the blue second selectively reflective layer 46b is incident on the blue light-emitting layer 35b. Thus, similarly to the first selectively reflective layer 44 and the second selectively reflective layer 46 for the blue pixel Pb in the third embodiment, the blue first selectively reflective layer 44b and the blue second selectively reflective layer 46b according to the fourth embodiment cause narrowing in bandwidth of the light emission spectrum of the blue pixel Pb.

Thus, the optical characteristics of the red first selectively reflective layer 44r and the red second selectively reflective layer 46r are preferably equivalent. A wavelength at the short wavelength end in the reflection band of each of the red first selectively reflective layer 44r and the red second selectively reflective layer 46r preferably satisfies, in a similar manner, the condition that the wavelength at the short wavelength end in the reflection band of the red selectively reflective layer 40r according to the second embodiment described above preferably satisfies for the red quantum dots. A wavelength at the long wavelength end in the reflection band of each of the red first selectively reflective layer 44r and the red second selectively reflective layer 46r preferably satisfies, in a similar manner, the condition that the wavelength at the long wavelength end in the reflection band of the red selectively reflective layer 40r according to the second embodiment described above preferably satisfies for the red quantum dots.

Furthermore, the optical characteristics of the green first selectively reflective layer 44g and the green second selectively reflective layer 46g are preferably equivalent. A wavelength at the short wavelength end in the reflection band of each of the green first selectively reflective layer 44g and the green second selectively reflective layer 46g preferably satisfies, in a similar manner, the condition that the wavelength at the short wavelength end in the reflection band of the green selectively reflective layer 40g according to the second embodiment described above preferably satisfies for the green quantum dots. A wavelength at the long wavelength end in the reflection band of each of the green first selectively reflective layer 44g and the green second selectively reflective layer 46g preferably satisfies, in a similar manner, the condition that the wavelength at the long wavelength end in the reflection band of the green selectively reflective layer 40g according to the second embodiment described above preferably satisfies for the green quantum dots.

Furthermore, the optical characteristics of the blue first selectively reflective layer 44b and the blue second selectively reflective layer 46b are preferably equivalent. A wavelength at the short wavelength end in the reflection band of each of the blue first selectively reflective layer 44b and the blue second selectively reflective layer 46b preferably satisfies, in a similar manner, the condition that the wavelength λₜ₁ at the short wavelength end in the reflection band of the selectively reflective layer 40 according to the first embodiment described above preferably satisfies for the blue quantum dots. A wavelength at the long wavelength end in the reflection band of each of the blue first selectively reflective layer 44b and the blue second selectively reflective layer 46b preferably satisfies, in a similar manner, the condition that the wavelength λₜ₂ at the long wavelength end in the reflection band of the selectively reflective layer 40 according to the first embodiment described above preferably satisfies for the blue quantum dots.

The red first selectively reflective layer 44r, the red second selectively reflective layer 46r, the green first selectively reflective layer 44g, the green second selectively reflective layer 46g, the blue first selectively reflective layer 44b, and the blue second selectively reflective layer 46b may have any configuration as long as they function as a bandpass filter having a high reflectivity in the reflection band as described above, and may be a dielectric multilayer film.

### Supplement

A light-emitting element according to a first aspect of the present invention includes a reflective electrode, a transparent electrode, a light-emitting layer provided between the reflective electrode and the transparent electrode, the light-emitting layer including quantum dots, and a selectively reflective layer provided at an opposite side to the light-emitting layer with respect to the transparent electrode, the selectively reflective layer having a reflection band having a higher reflectivity than a reflectivity of another band, and a wavelength at a long wavelength end in the reflection band of the selectively reflective layer is longer than a wavelength at which a light emission spectrum due to electroluminescence of the quantum dots has a half value of a peak value of the light emission spectrum due to the electroluminescence of the quantum dots at a shorter wavelength side than a peak wavelength of the light emission spectrum due to the electroluminescence of the quantum dots, and is shorter than a wavelength at which the light emission spectrum due to the electroluminescence of the quantum dots has the half value of the peak value of the light emission spectrum due to the electroluminescence of the quantum dots at a longer wavelength side than the peak wavelength of the light emission spectrum due to the electroluminescence of the quantum dots.

The light-emitting element according to a second aspect of the present invention may have, in the configuration according to the first aspect, a configuration satisfying that the peak wavelength of the light emission spectrum due to the electroluminescence of the quantum dots is λ₀, a full width at half maximum is δλ, the reflection band of the selectively reflective layer is from a wavelength λₜ₁ to a wavelength λₜ₂, λₜ₁<λₜ₂, and λ₀−δλ/2<λₜ₂<λ₀+δλ/2.

The light-emitting element according to a third aspect of the present invention may have, in the configuration according to the first or second aspect described above, a configuration in which the wavelength at the long wavelength end in the reflection band of the selectively reflective layer is longer than the peak wavelength of the light emission spectrum due to the electroluminescence of the quantum dots.

The light-emitting element according to a fourth aspect of the present invention may have, in the configuration according to any one of the first to third aspects described above, a configuration in which the wavelength at the short wavelength end in the reflection band of the selectively reflective layer is shorter, by a length being larger than or equal to a full width at half maximum of the light emission spectrum due to the electroluminescence of the quantum dots, than the wavelength at which the light emission spectrum due to the electroluminescence of the quantum dots has the half value of the peak value of the light emission spectrum due to the electroluminescence of the quantum dots, at the shorter wavelength side than the peak wavelength of the light emission spectrum due to the electroluminescence of the quantum dots.

The light-emitting element according to a fifth aspect of the present invention may have, in the configuration according to any one of the first to fourth aspects described above, a configuration in which the selectively reflective layer has a reflectivity being equal to or larger than 95% in the reflection band.

The light-emitting element according to a sixth aspect of the present invention may have, in the configuration according to any one of the first to fifth aspects described above, a configuration in which the selectively reflective layer has an absorption rate being equal to or less than 1% between (i) a wavelength being shorter, by a full width at half maximum of the light emission spectrum due to the electroluminescence of the quantum dots, than the wavelength at which the light emission spectrum due to the electroluminescence of the quantum dots has the half value of the peak value of the light emission spectrum due to the electroluminescence of the quantum dots, at the shorter wavelength side than the peak wavelength of the light emission spectrum due to the electroluminescence of the quantum dots, and (ii) a wavelength being longer, by the full width at half maximum of the light emission spectrum due to the electroluminescence of the quantum dots, than the wavelength at which the light emission spectrum due to the electroluminescence of the quantum dots has the half value of the peak value of the light emission spectrum due to the electroluminescence of the quantum dots, at the longer wavelength side than the peak wavelength of the light emission spectrum due to the electroluminescence of the quantum dots.

The light-emitting element according to a seventh aspect of the present invention may have, in the configuration according to any one of the first to sixth aspects described above, a configuration in which the selectively reflective layer is a dielectric multilayer film, and the dielectric multilayer film is a layered body of a first dielectric film and a second dielectric film having a dielectric constant different from a dielectric constant of the first dielectric film.

The light-emitting element according to an eighth aspect of the present invention may have, in the configuration according to the seventh aspect described above, a configuration in which the first dielectric film contains at least one of titanium oxide, niobium pentoxide, and tantalum pentoxide.

The light-emitting element according to a ninth aspect of the present invention may have, in the configuration according to the seventh or eighth aspect described above, a configuration in which the dielectric constant of the first dielectric film is equal to or greater than 4.8 and equal to or less than 6.0.

The light-emitting element according to a tenth aspect of the present invention may have, in the configuration according to any one of the seventh to ninth aspects described above, a configuration in which the second dielectric film contains at least one of silicon oxide, magnesium fluoride, and aluminum oxide.

The light-emitting element according to an eleventh aspect of the present invention may have, in the configuration according to any one of the seventh to tenth aspects described above, a configuration in which the dielectric constant of the first dielectric film is equal to or greater than 1.9 and equal to or less than 3.3.

The light-emitting element according to a twelfth aspect of the present invention may have, in the configuration according to any one of the seventh to eleventh aspects described above, a configuration in which a dielectric film closest to the transparent electrode among dielectric films included in the dielectric multilayer film is the second dielectric film.

The light-emitting element according to a thirteenth aspect of the present invention may have, in the configuration according to any one of the seventh to twelfth aspects described above, a configuration in which the peak wavelength of the light emission spectrum due to the electroluminescence of the quantum dots is equal to or greater than 400 nm and equal to or less than 500 nm, a thickness of the first dielectric film is equal to or greater than 126 nm and equal to or less than 157 nm, and a thickness of the second dielectric film is equal to or greater than 194 nm and equal to or less than 242 nm.

The light-emitting element according to a fourteenth aspect of the present invention may have, in the configuration according to any one of the seventh to twelfth aspects described above, a configuration in which the peak wavelength of the light emission spectrum due to the electroluminescence of the quantum dots is equal to or greater than 500 nm and equal to or less than 600 nm, a thickness of the first dielectric film is equal to or greater than 157 nm and equal to or less than 189 nm, and a thickness of the second dielectric film is equal to or greater than 242 nm and equal to or less than 291 nm.

The light-emitting element according to a fifteenth aspect of the present invention may have, in the configuration according to any one of the seventh to twelfth aspects described above, a configuration in which the peak wavelength of the light emission spectrum due to the electroluminescence of the quantum dots is equal to or greater than 600 nm and equal to or less than 780 nm, a thickness of the first dielectric film is equal to or greater than 189 nm and equal to or less than 246 nm, and a thickness of the second dielectric film is equal to or greater than 291 nm and equal to or less than 378 nm.

The light-emitting element according to a sixteenth aspect of the present invention may have, in the configuration according to any one of the seventh to fifteenth aspects, a configuration according to any one of claims 7 to 15, in which a sum of the number of layers of the first dielectric film and the number of layers of the second dielectric film included in the dielectric multilayer film is equal to or greater than three.

The light-emitting element according to a seventeenth aspect of the present invention may have, in the configuration according to any one of the first to sixteenth aspects, a configuration in which the light-emitting element further includes a photoluminescence layer provided between the selectively reflective layer and the transparent electrode, and the photoluminescence layer is configured to be excited by light emitted by the light-emitting layer and configured to emit light of a color identical to a color of the light emitted by the light-emitting layer.

A display device according to an eighteenth aspect of the present invention includes a light-emitting element including a transparent electrode, a reflective electrode, and a light-emitting layer, the light-emitting element serving as a red pixel, a light-emitting element including a transparent electrode, a reflective electrode, and a light-emitting layer, the light-emitting element serving as a green pixel, and the light-emitting element having the configuration according to any one of the first to seventeenth aspects described above, the light-emitting element serving as a blue pixel, and the selectively reflective layer of the blue pixel is formed across the red pixel, the green pixel, and the blue pixel.

A display device according to a nineteenth aspect of the present invention includes a light-emitting element including a transparent electrode, a reflective electrode, and a light-emitting layer, the light-emitting element serving as a red pixel, a light-emitting element including a transparent electrode, a reflective electrode, and a light-emitting layer, the light-emitting element serving as a green pixel, and the light-emitting element having the configuration according to any one of the first to seventeenth aspects described above, the light-emitting element serving as a blue pixel, and the selectively reflective layer of the blue pixel is formed only in the blue pixel.

A display device according to a twentieth aspect of the present invention includes the light-emitting element having the configuration according to any one of the first to seventeenth aspects describe above, the light-emitting element serving as a blue pixel, the light-emitting element having the configuration according to any one of the first to seventeenth aspects describe above, the light-emitting element serving as a red pixel, and the light-emitting element having the configuration according to any one of the first to seventeenth aspects describe above, the light-emitting element serving as a green pixel.

The display device according to a twenty-first aspect of the present invention may have, in the configuration according to the eighteenth or nineteenth aspect described above, a configuration in which the transparent electrode of the blue pixel is formed integrally with the transparent electrodes of the red pixel and the green pixel.

The display device according to a twenty-second aspect of the present invention may have, in the configuration according to the nineteenth or twentieth aspect described above, a configuration in which the transparent electrode of the blue pixel is formed separately from the transparent electrodes of the red pixel and the green pixel.

The display device according to a twenty-third aspect of the present invention may have, in the configuration according to the twenty-second aspect described above, a configuration in which the transparent electrode of the blue pixel is surrounded by a light-blocking body configured to block light of the blue pixel.

The display device according to a twenty-fourth aspect of the present invention may have, in the configuration according to the twenty-third aspect described above, a configuration in which the selectively reflective layer of the blue pixel is surrounded by the light-blocking body.

A light-emitting element according to a twenty-fifth aspect of the present invention includes a first transparent electrode, a second transparent electrode, a light-emitting layer provided between the first transparent electrode and the second transparent electrode, the light-emitting layer including a quantum dots, a first selectively reflective layer provided at an opposite side to the light-emitting layer with respect to the first transparent electrode, the first selectively reflective layer having a reflection band having a higher reflectivity than a reflectivity of another band, and a second selectively reflective layer provided at an opposite side to the light-emitting layer with respect to the second transparent electrode, the second selectively reflective layer having a reflection band having a higher reflectivity than a reflectivity of another band, a wavelength at a long wavelength end in the reflection band of the first selectively reflective layer is longer than a wavelength at which a light emission spectrum due to electroluminescence of the quantum dots has a half value of a peak value of the light emission spectrum due to the electroluminescence of the quantum dots at a shorter wavelength side than a peak wavelength of the light emission spectrum due to the electroluminescence of the quantum dots, and is shorter than a wavelength at which the light emission spectrum due to the electroluminescence of the quantum dots has the half value of the peak value of the light emission spectrum due to the electroluminescence of the quantum dots at a longer wavelength side than the peak wavelength of the light emission spectrum due to the electroluminescence of the quantum dots, and a wavelength at a long wavelength end in the reflection band of the second selectively reflective layer is longer than the wavelength at which the light emission spectrum due to the electroluminescence of the quantum dots has the half value of the peak value of the light emission spectrum due to the electroluminescence of the quantum dots at the shorter wavelength side than the peak wavelength of the light emission spectrum due to the electroluminescence of the quantum dots, and is shorter than the wavelength at which the light emission spectrum due to the electroluminescence of the quantum dots has the half value of the peak value of the light emission spectrum due to the electroluminescence of the quantum dots at the longer wavelength side than the peak wavelength of the light emission spectrum due to the electroluminescence of the quantum dots.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### REFERENCE SIGNS LIST

22 Anode (transparent electrode, second transparent electrode)
23 Edge cover (light-blocking body)
25 Cathode (reflective electrode, first transparent electrode)
35b Blue light-emitting layer
35g Green light-emitting layer
35r Red light-emitting layer
40 Selectively reflective layer (dielectric multilayer film)
40b Blue selectively reflective layer (dielectric multilayer film)
40g Green selectively reflective layer (dielectric multilayer film)
40r Red selectively reflective layer (dielectric multilayer film)
41 First dielectric film
42 Second dielectric film
Pr Red pixel (light-emitting element)
Pg Green pixel (light-emitting element)
Pb Blue pixel (light-emitting element)
44 First selectively reflective layer
44b Blue first selectively reflective layer
44g Green first selectively reflective layer
44r Red first selectively reflective layer
45 Photoluminescence layer
46 Second selectively reflective layer
46b Blue second selectively reflective layer
46g Green second selectively reflective layer
46r Red second selectively reflective layer

1. A light-emitting element comprising:
a reflective electrode;
a transparent electrode;
a light-emitting layer provided between the reflective electrode and the transparent electrode, the light-emitting layer including quantum dots; and
a selectively reflective layer provided at an opposite side to the light-emitting layer with respect to the transparent electrode, the selectively reflective layer having a reflection band having a higher reflectivity than a reflectivity of another band,
wherein a wavelength at a long wavelength end in the reflection band of the selectively reflective layer
is longer than a wavelength at which a light emission spectrum due to electroluminescence of the quantum dots has a half value of a peak value of the light emission spectrum due to the electroluminescence of the quantum dots at a shorter wavelength side than a peak wavelength of the light emission spectrum due to the electroluminescence of the quantum dots, and
is shorter than a wavelength at which the light emission spectrum due to the electroluminescence of the quantum dots has the half value of the peak value of the light emission spectrum due to the electroluminescence of the quantum dots at a longer wavelength side than the peak wavelength of the light emission spectrum due to the electroluminescence of the quantum dots.

2. The light-emitting element according to claim 1,
wherein the peak wavelength of the light emission spectrum due to the electroluminescence of the quantum dots is λ₀, a full width at half maximum is δλ, the reflection band of the selectively reflective layer is from a wavelength λₜ₁ to a wavelength λₜ₂, where λₜ₁<λₜ₂, and λ₀−δλ/2<λₜ₂<λ₀+δλ/2.

3. The light-emitting element according to claim 1,
wherein the wavelength at the long wavelength end in the reflection band of the selectively reflective layer is longer than the peak wavelength of the light emission spectrum due to the electroluminescence of the quantum dots.

4. The light-emitting element according to claim 1,
wherein the wavelength at the short wavelength end in the reflection band of the selectively reflective layer is shorter, by a length being larger than or equal to a full width at half maximum of the light emission spectrum due to the electroluminescence of the quantum dots, than the wavelength at which the light emission spectrum due to the electroluminescence of the quantum dots has the half value of the peak value of the light emission spectrum due to the electroluminescence of the quantum dots, at the shorter wavelength side than the peak wavelength of the light emission spectrum due to the electroluminescence of the quantum dots.

5. (canceled)

6. The light-emitting element according to claim 1,
wherein the selectively reflective layer has an absorption rate being equal to or less than 1% between (i) a wavelength being shorter, by a full width at half maximum of the light emission spectrum due to the electroluminescence of the quantum dots, than the wavelength at which the light emission spectrum due to the electroluminescence of the quantum dots has the half value of the peak value of the light emission spectrum due to the electroluminescence of the quantum dots, at the shorter wavelength side than the peak wavelength of the light emission spectrum due to the electroluminescence of the quantum dots, and (ii) a wavelength being longer, by the full width at half maximum of the light emission spectrum due to the electroluminescence of the quantum dots, than the wavelength at which the light emission spectrum due to the electroluminescence of the quantum dots has the half value of the peak value of the light emission spectrum due to the electroluminescence of the quantum dots, at the longer wavelength side than the peak wavelength of the light emission spectrum due to the electroluminescence of the quantum dots.

7. The light-emitting element according to claim 1,
wherein the selectively reflective layer is a dielectric multilayer film, and
the dielectric multilayer film is a layered body of a first dielectric film and a second dielectric film having a dielectric constant different from a dielectric constant of the first dielectric film.

8. (canceled)

9. (canceled)

10. (canceled)

11. (canceled)

12. The light-emitting element according claim 7,
wherein a dielectric film closest to the transparent electrode among dielectric films included in the dielectric multilayer film is the second dielectric film.

13. The light-emitting element according to claim 7,
wherein the peak wavelength of the light emission spectrum due to the electroluminescence of the quantum dots is equal to or greater than 400 nm and equal to or less than 500 nm,
a thickness of the first dielectric film is equal to or greater than 126 nm and equal to or less than 157 nm, and
a thickness of the second dielectric film is equal to or greater than 194 nm and equal to or less than 242 nm.

14. The light-emitting element according to claim 7,
wherein the peak wavelength of the light emission spectrum due to the electroluminescence of the quantum dots is equal to or greater than 500 nm and equal to or less than 600 nm,
a thickness of the first dielectric film is equal to or greater than 157 nm and equal to or less than 189 nm, and
a thickness of the second dielectric film is equal to or greater than 242 nm and equal to or less than 291 nm.

15. The light-emitting element according to claim 7,
wherein the peak wavelength of the light emission spectrum due to the electroluminescence of the quantum dots is equal to or greater than 600 nm and equal to or less than 780 nm,
a thickness of the first dielectric film is equal to or greater than 189 nm and equal to or less than 246 nm, and
a thickness of the second dielectric film is equal to or greater than 291 nm and equal to or less than 378 nm.

16. The light-emitting element according to claim 7,
wherein a sum of the number of layers of the first dielectric film and the number of layers of the second dielectric film included in the dielectric multilayer film is equal to or greater than three.

17. The light-emitting element according to claim 1, further comprising:
a photoluminescence layer provided between the selectively reflective layer and the transparent electrode,
wherein the photoluminescence layer is configured to be excited by light emitted by the light-emitting layer and configured to emit light of a color identical to a color of the light emitted by the light-emitting layer.

18. A display device comprising:
a light-emitting element including a transparent electrode, a reflective electrode, and a light-emitting layer, the light-emitting element serving as a red pixel;
a light-emitting element including a transparent electrode, a reflective electrode, and a light-emitting layer, the light-emitting element serving as a green pixel; and
the light-emitting element according to claim 1, the light-emitting element serving as a blue pixel,
wherein the selectively reflective layer of the blue pixel is formed across the red pixel, the green pixel, and the blue pixel.

19. A display device comprising:
a light-emitting element including a transparent electrode, a reflective electrode, and a light-emitting layer, the light-emitting element serving as a red pixel;
a light-emitting element including a transparent electrode, a reflective electrode, and a light-emitting layer, the light-emitting element serving as a green pixel; and
the light-emitting element according to claim 1, the light-emitting element serving as a blue pixel,
wherein the selectively reflective layer of the blue pixel is formed only in the blue pixel.

20. A display device comprising:
the light-emitting element according to claim 1, the light-emitting element serving as a blue pixel;
the light-emitting element according to claim 1, the light-emitting element serving as a red pixel; and
the light-emitting element according to claim 1, the light-emitting element serving as a green pixel.

21. The display device according to claim 18,
wherein the transparent electrode of the blue pixel is formed integrally with the transparent electrodes of the red pixel and the green pixel.

22. The display device according to claim 19,
wherein the transparent electrode of the blue pixel is formed separately from the transparent electrodes of the red pixel and the green pixel.

23. The display device according to claim 22,
wherein the transparent electrode of the blue pixel is surrounded by a light-blocking body configured to block light of the blue pixel.

24. The display device according to claim 23,
wherein the selectively reflective layer of the blue pixel is surrounded by the light-blocking body.

25. A light-emitting element comprising:
a first transparent electrode;
a second transparent electrode;
a light-emitting layer provided between the first transparent electrode and the second transparent electrode, the light-emitting layer including quantum dots;
a first selectively reflective layer provided at an opposite side to the light-emitting layer with respect to the first transparent electrode, the first selectively reflective layer having a reflection band having a higher reflectivity than a reflectivity of another band; and
a second selectively reflective layer provided at an opposite side to the light-emitting layer with respect to the second transparent electrode, the second selectively reflective layer having a reflection band having a higher reflectivity than a reflectivity of another band,
wherein a wavelength at a long wavelength end in the reflection band of the first selectively reflective layer
is longer than a wavelength at which a light emission spectrum due to electroluminescence of the quantum dots has a half value of a peak value of the light emission spectrum due to the electroluminescence of the quantum dots at a shorter wavelength side than a peak wavelength of the light emission spectrum due to the electroluminescence of the quantum dots, and
is shorter than a wavelength at which the light emission spectrum due to the electroluminescence of the quantum dots has the half value of the peak value of the light emission spectrum due to the electroluminescence of the quantum dots at a longer wavelength side than the peak wavelength of the light emission spectrum due to the electroluminescence of the quantum dots, and
a wavelength at a long wavelength end in the reflection band of the second selectively reflective layer
is longer than the wavelength at which the light emission spectrum due to the electroluminescence of the quantum dots has the half value of the peak value of the light emission spectrum due to the electroluminescence of the quantum dots at the shorter wavelength side than the peak wavelength of the light emission spectrum due to the electroluminescence of the quantum dots, and
is shorter than the wavelength at which the light emission spectrum due to the electroluminescence of the quantum dots has the half value of the peak value of the light emission spectrum due to the electroluminescence of the quantum dots at the longer wavelength side than the peak wavelength of the light emission spectrum due to the electroluminescence of the quantum dots.
